(19) United States
(12) Patent Application Publication
(10) Pub. No.: US 2015/0214871 A1
(43) Pub. Date: Jul. 30, 2015

(54) Method and System for Determining Motor Shaft Position

(71) Applicant: Moog Inc., East Aurora, NY (US)

(72) Inventor: Frank J. Saglime, III, West Seneca, NY (US)

(21) Appl. No.: 14/166,577

(22) Filed: Jan. 28, 2014

(51) Int. Cl. H02P 6/00; G01R 25/04; H02P 6/12

(52) U.S. Cl. CPC H02P 6/007; H02P 6/12; G01R 25/04

(57) ABSTRACT

The present disclosure provides methods and systems for determining the rotor position of a BLDC motor having a saliency. Techniques according to the present disclosure advantageously may be used to determine a rotor position of a rotor which is not moving.

### FIELD OF THE DISCLOSURE

The invention relates to control of a direct current (“DC”) motor, and more particularly to methods and devices for self-sensing rotor position in a DC motor.

### BACKGROUND OF THE DISCLOSURE

In order to properly commutate a brushless DC (“BLDC”) motor, the position of the rotor, relative to the stator, must be known. Determination of the rotor position is traditionally accomplished using Hall-Effect devices (“HEDs”), resolvers, and/or encoders. However, the addition of such rotor position measuring device to a motor may increase the cost of the motor and may decrease the reliability of the motor due to the potential failure of additional components.

Sensorless techniques for determining rotor (i.e., shaft) position have been developed in the past. For example, techniques for determining rotor position based on so-called “back EMF” have been used in the past. However, such sensorless techniques are not able to determine the position of the rotor when the rotor is moving at low speed or not moving at all. Thus, such techniques are not useful for proper commutation of a DC motor from start-up.

There is a long-felt need for a technique to determine the rotor position of a BLDC motor without the use of additional measuring components.

### BRIEF SUMMARY OF THE DISCLOSURE

The present disclosure provides methods and systems for determining the rotor position of a BLDC motor having a saliency using phase-shifted (skewed) PWM drive signals to create a current ripple. Techniques according to the present disclosure may advantageously be used to determine a rotor position of a rotor which is not moving.

### DESCRIPTION OF THE DRAWINGS

For a fuller understanding of the nature and objects of the disclosure, reference should be made to the following detailed description taken in conjunction with the accompanying drawings, in which:

FIG. 1A is a diagram of components of an interior permanent magnet (“IPM”) motor, viewed along a rotational axis of the rotor, and showing rotor magnet positions;

FIG. 1B is a diagram of components of an surface permanent magnet (“SPM”) motor, viewed along a rotational axis of the rotor, and showing rotor magnet positions;

FIG. 2A is a diagram of a prior art PWM controller scheme;

FIG. 2B is a diagram of a PWM scheme according to an embodiment of the present disclosure;

FIG. 3 is a block diagram showing signals used in an embodiment of a system according to an embodiment of the present disclosure, and showing one example of a set of components that can be embodied in an field-programmable gate array (“FPGA”) or a digital signal processor (“DSP) (dashed box);

FIG. 4 is a diagram of a controller according to another embodiment of the present disclosure, wherein the controller is depicted connected to a motor;

FIG. 5 is a diagram of a processor-based controller according to another embodiment of the present invention, wherein the controller is depicted connected to a motor; and

FIG. 6 is a flowchart of a method according to another embodiment of the present disclosure.

### DETAILED DESCRIPTION OF THE DISCLOSURE

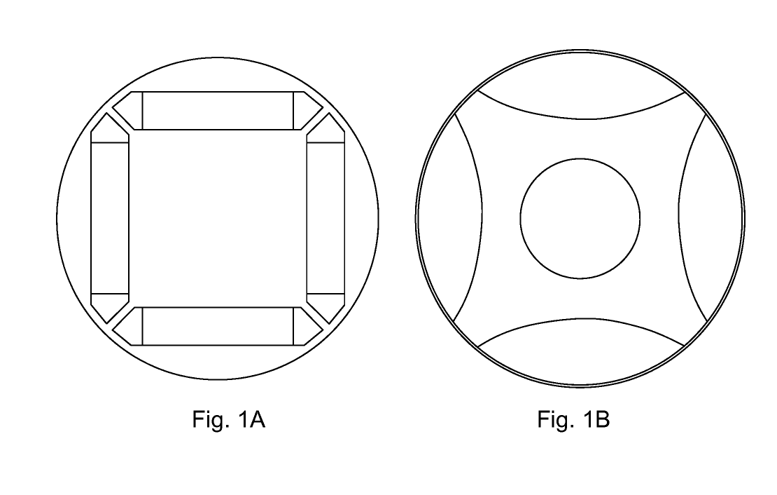

The present disclosure describes methods and systems for determining a rotor position in a permanent magnet direct current (“DC”) motor, such as a brushless DC (“BLDC”) motor having a saliency. Such motors may be, for example, interior permanent magnet (“IPM”) motors or surface permanent magnet (“SPM”) motors with shaped magnets (see, e.g., FIGS. 1A and 1B). Such motors have phase inductances that vary with rotor position. The present disclosure utilizes this relationship between inductance and rotor position and provides techniques for determining rotor position based on the measured inductances of the motor.

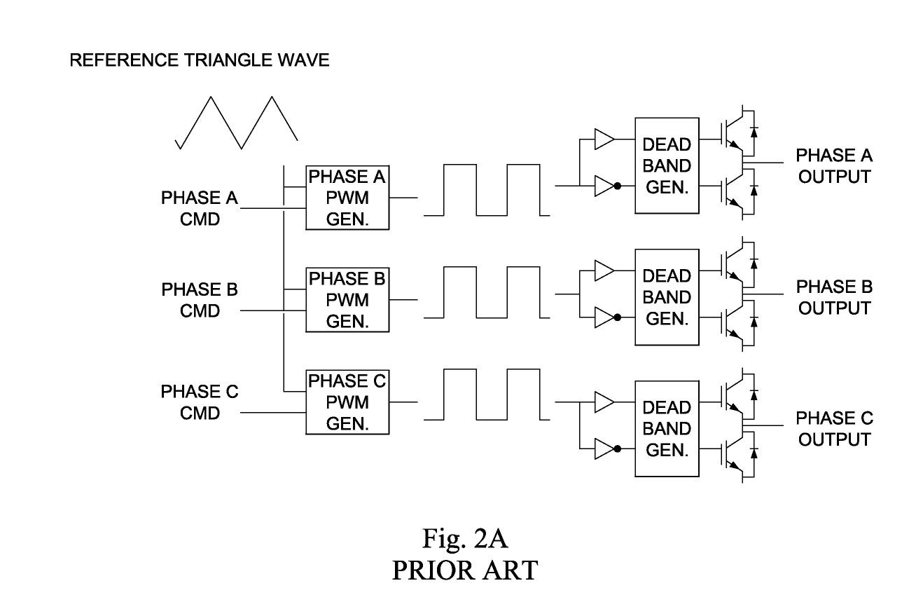

Pulse-width modulation (“PWM”) drive signals are commonly used to drive BLDC motors. FIG. 2A depicts a block diagram of a typical PWM scheme for driving a three-phase BLDC motor, where a reference triangle wave signal having a PWM frequency is used to produce three PWM signals (one for each phase of the motor) based on three corresponding CMD signals. The resulting three PWM drive signals each have a frequency and a phase which corresponds to the common reference triangle wave signal.

The present disclosure provides a new PWM scheme which introduces a phase shift between at least two phases of a BLDC motor. FIG. 2B depicts a block diagram of one embodiment of the present PWM scheme wherein each of the PWM drive signals of a three-phase motor have a phase that is shifted relative to the other PWM drive signals. In the depicted embodiment, the phase shift of the PWM drive signals results from the use of three separate reference triangle wave signals to generate the corresponding PWM drive signals. The separate reference triangle wave signals may be substantially the same as one another (e.g., frequency, amplitude, waveform, etc.) except that each is phase-shifted. The phase shift may be a maximum phase shift or may be less than the maximum phase shift. For example, in a three-phase motor, where each phase of the motor is driven by a phase-shifted PWM drive signal, the signals may have a phase shifted by 120 degrees relative to one another. This represents the maximum phase shift in a three-phase scheme. In other embodiments, it may be advantageous to shift the phases by less than the maximum. For example, the phase may be shifted by some amount greater than 0 degrees and less than 120 degrees (in the example of a three-phase scheme).

The phase-shifted drive signals cause a ripple in the current used to drive the motor. Traditionally, designers have sought to minimize (or, ideally, to eliminate) such current ripples, particularly in low-inductance motors. Embodiments of the present disclosure utilize the current ripple to determine the phase inductances and derive the rotor position based on the inductances.

The present disclosure may be embodied as a method 100 for determining a rotational position of a rotor of a BLDC motor. The motor has at least two phases, each phase being driven by a corresponding PWM drive signal. In some embodiments, the motor has three phases, a first phase, a second phase, and a third phase, and the phases are driven by a first PWM drive signal, a second PWM drive signal, and a third PWM drive signal, respectively.

The method 100 comprises the step of shifting 103 a phase of the first PWM drive signal relative to a phase of the second PWM drive signal. In an embodiment of a three-phase BLDC motor, the method 100 may comprise the step of shifting 106 a phase of the third PWM drive signal relative to the phase of the first and second PWM drive signals. It should be noted that in a three-phase (or more) motor, shifting each phase is not required, so long as the drive signal for at least one phase is shifted. The PWM drive signals may be shifted 103 using any technique, such as, for example, generating each PWM drive signal from phase-shifted reference signals.

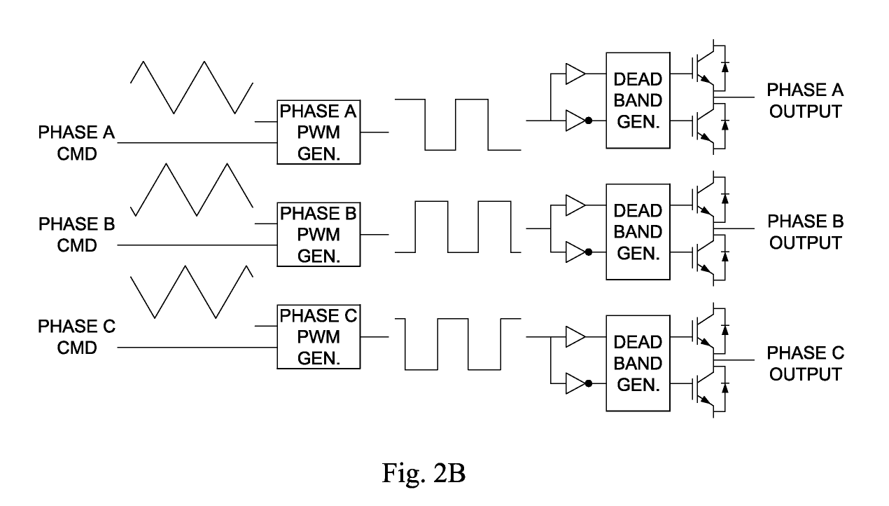

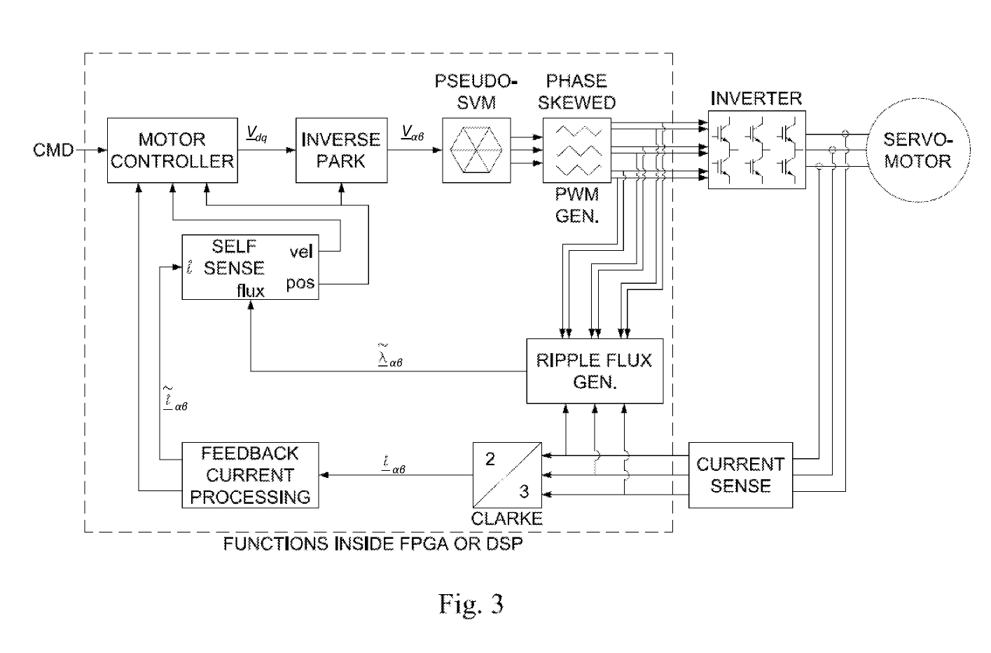

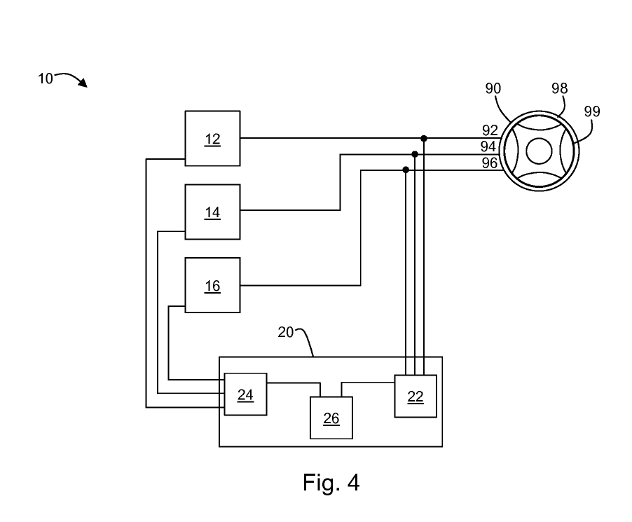

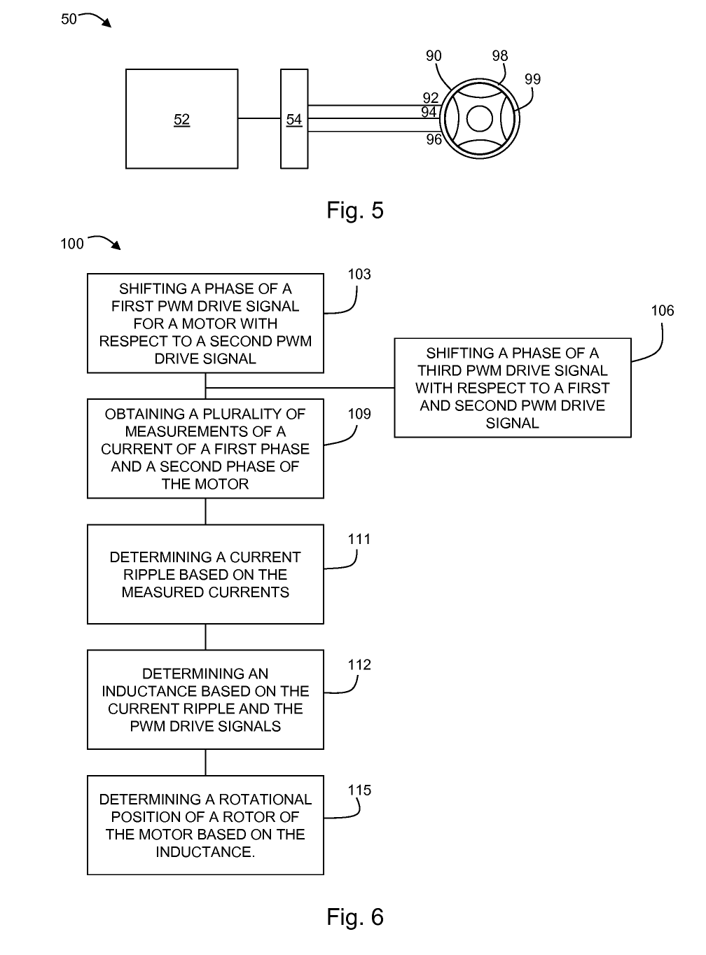

The method 100 further comprises the step of obtaining 109 a plurality of measurements, over a sampling period, of a current of the first phase and a current of the second phase of the motor. In embodiments where additional phases are shifted, the measurements may include corresponding measurements of the currents of the additional phases. FIG. 3 depicts a block diagram showing an exemplary embodiment wherein current is sensed in each phase of a three-phase motor. The number of measurements during the sampling period may be referred to as the “sampling rate.” The sampling rate may be higher than the frequency of the PWM drive signals. In some embodiments, the sampling rate is more than 10 times the frequency of the PWM drive signals. In some embodiments, the sampling rate is 100 times the frequency of the PWM drive signals, or more. For example, in a motor driven by PWM drive signals having a frequency of 10 kHz, the sampling rate may be 1 Msamples/sec (although the sampling period need not be 1 second).

A current ripple is determined 111 using the plurality of measurements. In an exemplary embodiment, the current measured over a PWM cycle is averaged. A line is extrapolated using this average current and the average current over the previous PWM cycle. This extrapolated line is then subtracted from the measured currents to provide the ripple current. Other techniques for deriving a ripple current useful for determining the inductance will be apparent in light of the present disclosure. An inductance is determined 112 over time based on the current ripple and the first and second PWM drive signals. The inductance may be determined 112 using the known voltage of the PWM drive signals and the determined 111 current ripple by way of the equation

$$v = L \frac{d i}{d t} .$$

In some embodiments, it is advantageous to determine 112 the inductance by integrating the voltages (referred to herein as a voltage “flux,” ‘λ’) and using the determined 111 current ripple such that inductance is determined according to λ=Li. Further details are provided below for determining the inductances as a function of rotational position (θ).

The method 100 further comprises the step of determining 115 a rotational position of the rotor based on the determined 112 inductance. Again, details of deriving the position of the rotor based on the inductance is provided below.

The present disclosure may be embodied as a controller 10 for a three-phase BLDC motor 90 having a saliency. A suitable motor 90 for connection to the present controller 10 has a rotor 99 which is rotatable within a stator 98. The rotor 99 is driven by coils of a first phase 92, a second phase 94, and a third phase 96 of the motor 90. The controller 10 comprises a first PWM generator 12, which is adapted to be in electrical communication with the first phase 92 of the motor 90. For example, the first PWM generator 12 may communicate with the first phase 92 of the motor 90 via electrical leads and an electrical connector. The first PWM generator 12 is configured to generate a first PWM drive signal having a drive frequency (i.e., the frequency of the PWM pulses) and a first signal phase.

The controller 10 comprises a second PWM generator 14, which is adapted to be in electrical communication with the second phase 94 of the motor 90. The second PWM generator 14 is configured to generate a second PWM drive signal having the drive frequency and a second signal phase. As such, the second PWM drive signal has the same frequency as the first PWM drive signal, but each pulse is shifted in time relative to the pulses of the first PWM drive signal by a phase shift value. The controller 10 comprises a third PWM generator 16, which is adapted to be in electrical communication with the third phase 96 of the motor 90. The third PWM generator 16 is configured to generate a third PWM drive signal having the drive frequency and a third signal phase—thereby having a pulse train which is phase-shifted relative to the pulses of the first and second PWM drive signals.

It should be noted that other components may be disposed in the electrical connection between the PWM generators 12, 14, 16 and the motor 90. For example, the controller 10 may include an inverter as is commonly known with such BLDC motor controllers. As such, the electrical communication between the PWM generators 12, 14, 16 and the motor 90 need not be direct. PWM generators 12, 14, 16 may be separate, or may be embodied within one or more PWM generators configured to generate one or more PWM drive signals appropriate for the presently disclosed techniques.

The controller 10 comprises a ripple analyzer 20 configured to obtain a plurality of voltage samples of each of the PWM drive signals and a plurality of current samples of each phase of the motor 90 at a sampling rate. In some embodiments, the ripple analyzer 20 is in communication with each PWM generator 12, 14, 16 and receives a value of the voltage of each PWM drive signal from the PWM generators 12, 14, 16. In other embodiments, the ripple analyzer 20 is configured to receive the PWM drive signal voltage samples from a voltage sensor. In other embodiments, the ripple analyzer 20 is configure to measure voltages. Other techniques for obtaining voltage samples will be apparent in light of the present disclosure. The ripple analyzer 20 determines a rotational (angular) position of the rotor 99. The rotational position of the rotor 99 may be determined as a position relative to the stator 98.

The ripple analyzer 20 may further comprise a current sensor 22 configured to obtain a plurality of current samples of each phase 92, 94, 96 of the motor 90 at the sampling rate. The current sensor 22 may be configured to determine a ripple current based on the current samples. The ripple analyzer 20 may further comprise a ripple flux generator 24 configured to obtain a plurality of voltage samples of each PWM drive signal at the sampling rate. As described above with respect to the ripple analyzer 20, the ripple flux generator 24 may obtain the plurality of voltages in various ways. The ripple flux generator 24 is configured to determine a ripple flux based on the plurality of voltage samples.

The ripple analyzer 20 may further comprise a position sensor 26 in electrical communication with the current sensor 22 and the ripple flux generator 24. In this manner, the position sensor 26 may be configured to receive the ripple current and ripple flux from the current sensor 22 and the ripple flux generator 24, respectively. The position sensor 26 is configured to determine a position of the rotor 99 of the motor 90 based on the ripple current and the ripple flux. Additional detail regarding the determination of ripple current, ripple flux, and rotor 99 position is provided below. A signal embodying the determined position of the rotor 99 may be used in a feedback loop to adjust the speed or other characteristics of the motor 90.

In another embodiment of the present disclosure, a processor-based controller 50 for a BLDC motor 90 having a saliency is provided. The controller 50 comprises a processor 52. The processor 52 may be any type of processor including a general-use processor, such as, for example, a microprocessor or microcontroller. In some embodiments, the processor 52 and programming may be implemented in hardware such as, for example, a field-programmable gate array (“FPGA”) or a digital signal processor (“DSP”), which may be an application-specific integrated circuit (“ASIC”), etc. Although described as a processor, it is to be appreciated that the processor 52 may be implemented in practice by any combination of hardware, software, and firmware. Also, the processor 52 steps as described herein may be performed by one unit, or divided up among different components, each of which may be implemented in turn by any combination of hardware, software, and firmware. Program code or instructions for the processor 52 to implement the various methods and steps described herein may be stored in processor readable storage media, such as, for example, memory, which may be a non-transitory medium.

The controller 50 comprises interface circuitry 54 configured to operable couple the processor 52 to the motor 90. Suitable interface circuitry 54 will be apparent to one having skill in the art in light of the present disclosure. Interface circuitry 54 may comprise, for example, electrical leads, electrical connectors, inverters, dead-band generators, etc., and combinations.

The processor 52 is programmed to perform any method according to the present disclosure. For example, in one embodiment, the processor 52 is programmed to provide a first PWM drive signal having a first voltage waveform to a first phase 92 of the motor 90 and a second PWM drive signal having a second voltage waveform to a second phase 94 of the motor 90, the first and second PWM drive signals being phase-shifted relative to each other. In the example, the processor 52 may be further programmed to obtain a plurality of measurements of a current of each phase 92, 94 of the motor over time and determine a position of a rotor 99 of the motor 90 based on the first and second voltage waveforms and the measured currents of the motor 90.

The present disclosure has been found to advantageously provide a fault detection capability for the current sensor and other circuitry. This capability results from the requirement of a ripple current. As such, if a ripple current is not present (e.g., not detected), a fault condition exists. Therefore, the present disclosure may be embodied as a method and/or system for fault detection, wherein a ripple current is determined by techniques such as those described herein, and wherein if the ripple current is determined to be non-existent (or the ripple current is outside of one or more pre-determined parameters), a fault condition exists. Embodiments of such methods for fault detection may be used in conjunction with the rotor position embodiments disclosed herein, or separately from the rotor position embodiments.

Exemplary Determination of Shaft Position

The present disclosure was confirmed using a MATLAB/Simulink model and was tested using the dSPACE prototyping system to drive an IPM motor. The following describes an exemplary mathematical derivation of rotor position using phase-shifted PWM drive signals, which can be embodied in circuitry and/or programming.

Although most motors have three phases, mathematically it is more convenient to work with a two phase equivalent for position sensing. It is possible to go directly from a complete mathematical motor model in three phases to two, but it is not convenient to deal rotor saliency directly. And even if the assumption is made that the inductances and mutual inductance vary sinusoidally with rotor angle (but offset by 120 degrees), the math is still somewhat tedious. A simpler approach is to start with the motor model in the dq reference frame and work back to the two phase model in the stationary (αβ) reference frame.

Motor Model

dq Reference Frame

Equation 1 shows the dq motor equation in its general form where L_{d} does not necessarily equal L_{q}. For many motors L_{d}≈L_{q}, but this is not true for IPM's or salient pole machines. Furthermore, it is possible to design in a saliency intentionally by shaping the magnets used on the rotor (see, e.g., FIG. 1B).

$$[ \begin{matrix}{v}_{d} \\ {v}_{q}\end{matrix} ] = [ \begin{matrix}R & 0 \\ 0 & R\end{matrix} ] [ \begin{matrix}{i}_{d} \\ {i}_{q}\end{matrix} ] + [ \begin{matrix}{L}_{d} & 0 \\ 0 & {L}_{q}\end{matrix} ] \frac{d }{d t} [ \begin{matrix}{i}_{d} \\ {i}_{q}\end{matrix} ] + ω [ \begin{matrix}0 & - {L}_{d} \\ {L}_{q} & 0\end{matrix} ] [ \begin{matrix}{i}_{d} \\ {i}_{q}\end{matrix} ] + ω [ \begin{matrix}0 \\ {Ψ}_{f}\end{matrix} ] \qquad ( 1 )$$

This can be written more compactly as:

$${\underline{v}}_{dq} = ℝ {\underline{i}}_{dq} + 𝕃 \frac{d }{d t} {\underline{i}}_{dq} + ω [ \begin{matrix}0 & - {L}_{d} \\ {L}_{q} & 0\end{matrix} ] {\underline{i}}_{dq} + ω [ \begin{matrix}0 \\ {Ψ}_{f}\end{matrix} ] \qquad ( 2 )$$

Noting that:

$${\underline{v}}_{dq} = [ \begin{matrix}{v}_{d} \\ {v}_{q}\end{matrix} ] , {\underline{i}}_{dq} = [ \begin{matrix}{i}_{d} \\ {i}_{q}\end{matrix} ] , ℝ = [ \begin{matrix}R & 0 \\ 0 & R\end{matrix} ] , \\ and$$

$$𝕃 = [ \begin{matrix}{L}_{d} & 0 \\ 0 & {L}_{q}\end{matrix} ]$$

αβ Reference Frame

By using the park transform (a rotational transform), equation 2 is converted to the αβ reference frame using the relations:

$$\begin{matrix}{\underline{v}}_{dq} = {ℙ}^{- 1} ( θ ) {\underline{v}}_{α β} \\ {\underline{v}}_{αβ} = ℙ ( θ ) {\underline{v}}_{dq} & ( 3 ) \\ {\underline{i}}_{dq} = {ℙ}^{- 1} ( θ ) {\underline{i}}_{α β} \\ {\underline{i}}_{αβ} = ℙ ( θ ) {\underline{i}}_{dq} \\ Where & ( 4 ) \\ {ℙ}^{- 1} ( θ ) = [ \begin{matrix}cos θ & - sin θ \\ sin θ & cos θ\end{matrix} ] \\ ℙ ( θ ) = [ \begin{matrix}cos θ & sin θ \\ - sin θ & cos θ\end{matrix} ] & ( 5 )\end{matrix}$$

Substituting equations 3 and 4 into equation 2, yields:

$${ℙ}^{- 1} ( θ ) {\underline{v}}_{αβ} = ( ℝ + ω [ \begin{matrix}0 & - {L}_{q} \\ {L}_{q} & 0\end{matrix} ] ) {ℙ}^{- 1} ( θ ) {\underline{i}}_{αβ} + 𝕃 \frac{d }{d t} ( {ℙ}^{- 1} ( θ ) {\underline{i}}_{αβ} ) + ω [ \begin{matrix}0 \\ {Ψ}_{f}\end{matrix} ] \qquad ( 6 )$$

Then, solving for ν_{αβ} provides:

$${\underline{v}}_{αβ} = ℝ {\underline{i}}_{α β} + ω ℙ ( θ ) [ \begin{matrix}0 & - {L}_{q} \\ {L}_{q} & 0\end{matrix} ] {ℙ}^{- 1} ( θ ) {\underline{i}}_{αβ} + ℙ ( θ ) 𝕃 \frac{d }{d t} ( {ℙ}^{- 1} ( θ ) {\underline{i}}_{αβ} ) + ωℙ ( θ ) [ \begin{matrix}0 \\ {Ψ}_{f}\end{matrix} ] \qquad ( 7 )$$

And, using the chain rule on the derivative provides:

$${\underline{v}}_{α β} = ℝ {\underline{ i}}_{α β} + ωℙ ( θ ) [ \begin{matrix}0 & - {L}_{d} \\ {L}_{q} & 0\end{matrix} ] {ℙ}^{- 1} ( θ ) {\underline{i}}_{αβ} + ωℙ ( θ ) 𝕃 \frac{d }{d θ} ( {ℙ}^{- 1} ( θ ) ) {\underline{i}}_{αβ} + ℙ ( θ ) {𝕃ℙ}^{- 1} ( θ ) \frac{d }{d t} ( {\underline{i}}_{αβ} ) + ωℙ ( θ ) [ \begin{matrix}0 \\ {Ψ}_{f}\end{matrix} ] \qquad ( 8 )$$

The following terms are evaluated:

$$ωℙ ( θ ) [ \begin{matrix}0 & - {L}_{d} \\ {L}_{q} & 0\end{matrix} ] {ℙ}^{- 1} ( θ ) , \\ ωℙ ( θ ) 𝕃 \frac{d }{d θ} ( {ℙ}^{- 1} ( θ ) ) ,$$

[symbol]

(θ) [symbol] ⁻¹(θ), resulting in:

$$\begin{matrix}ωℙ ( θ ) [ \begin{matrix}0 & - {L}_{d} \\ {L}_{q} & 0\end{matrix} ] {ℙ}^{- 1} ( θ ) = ω ( \frac{{L}_{d} + {L}_{q}}{2} [ \begin{matrix}0 & - 1 \\ 1 & 0\end{matrix} ] + \frac{{L}_{d} - {L}_{q}}{2} [ \begin{matrix}sin 2 θ & cos 2 θ \\ cos 2 θ & - sin 2 θ\end{matrix} ] ) & ( 9 ) \\ ωℙ ( θ ) 𝕃 \frac{d }{d θ} ( {ℙ}^{- 1} ( θ ) ) = ω ( \frac{{L}_{d} + {L}_{q}}{2} [ \begin{matrix}0 & - 1 \\ 1 & 0\end{matrix} ] - \frac{{L}_{d} - {L}_{q}}{2} [ \begin{matrix}sin 2 θ & cos 2 θ \\ cos 2 θ & - sin 2 θ\end{matrix} ] ) & ( 10 ) \\ ℙ ( θ ) {𝕃ℙ}^{- 1} ( θ ) = \frac{{L}_{d} + {L}_{q}}{2} [ \begin{matrix}1 & 0 \\ 0 & 1\end{matrix} ] - \frac{{L}_{d} - {L}_{q}}{2} [ \begin{matrix}- cos 2 θ & sin 2 θ \\ sin 2 θ & cos 2 θ\end{matrix} ] & ( 11 ) \\ ωℙ ( θ ) [ \begin{matrix}0 & - {L}_{d} \\ {L}_{q} & 0\end{matrix} ] {ℙ}^{- 1} ( θ ) + ωℙ ( θ ) 𝕃 \frac{d }{d θ} ( {ℙ}^{- 1} ( θ ) ) = ω ( {L}_{q} + {L}_{q} ) [ \begin{matrix}0 & - 1 \\ 1 & 0\end{matrix} ] & ( 12 )\end{matrix}$$

Remarkably, this means:

$$ωℙ ( θ ) [ \begin{matrix}0 & - {L}_{q} \\ {L}_{q} & 0\end{matrix} ] {ℙ}^{- 1} ( θ ) + ω ℙ ( θ ) 𝕃 \frac{d }{d θ} ( {ℙ}^{- 1} ( θ ) ) = ω ( {L}_{d} + {L}_{q} ) [ \begin{matrix}0 & - 1 \\ 1 & 0\end{matrix} ] \qquad ( 12 )$$

Which is independent of θ itself. This means that equation 8 can be greatly simplified as:

$${\underline{v}}_{αβ} = {𝕃}_{1} ( θ ) \frac{d }{d t} ( {\underline{i}}_{αβ} ) + ( ℝ + {ω𝕃}_{2} ) {\underline{i}}_{αβ} + ωℙ ( θ ) [ \begin{matrix}0 \\ {Ψ}_{f}\end{matrix} ] \qquad ( 13 )$$

Where:

$${𝕃}_{1} ( θ ) = ℙ ( θ ) {𝕃ℙ}^{- 1} ( θ ) \\ {𝕃}_{1} ( θ ) = \frac{{L}_{d} + {L}_{q}}{2} [ \begin{matrix}1 & 0 \\ 0 & 1\end{matrix} ] - \frac{{L}_{d} - {L}_{q}}{2} [ \begin{matrix}- cos 2 θ & sin 2 θ \\ sin 2 θ & cos 2 θ\end{matrix} ] \qquad ( 14 )$$

And:

$${𝕃}_{2} = ℙ ( θ ) [ \begin{matrix}0 & - {L}_{d} \\ {L}_{q} & 0\end{matrix} ] {ℙ}^{- 1} ( θ ) + ℙ ( θ ) 𝕃 \frac{d }{d θ} ( {ℙ}^{- 1} ( θ ) ) \\ {𝕃}_{2} = ( {L}_{d} + {L}_{q} ) [ \begin{matrix}0 & - 1 \\ 1 & 0\end{matrix} ] \qquad ( 15 )$$

But over one PWM cycle, ν_{αβ} and i_{αβ} have an average part and a part oscillates with the PWM:

ν_{αβ}=V_{αβ}+\tilde{ν}_{αβ} (16)

i_{αβ}=I_{αβ}+\tilde{ι}_{αβ} (17)

Where V_{αβ} and I_{αβ} are the average parts (over one PWM cycle) and \tilde{ν}_{αβ} and \tilde{ι}_{αβ} are the parts that oscillate with the PWM.

$${\underline{V}}_{α β} ( t ) = \frac{1}{{T}_{pwm}} {\int }_{t}^{t + {T}_{pwm}} {\underline{v}}_{α β} ( τ ) d τ \qquad ( 18 )$$

And because of this, integrating the oscillating part of ν_{αβ}(τ) (that is \tilde{ν}_{αβ}(τ)) gives:

∫ₜ^{t+T}^{_{pwm}}\tilde{ν}_{αβ}(τ)dτ=0 (19)

Note that the same holds true for I_{αβ} and \tilde{ι}_{αβ} as well. Then substitution of equations 16 and 17 into equation 13 yields:

$${\underline{V}}_{α β} + {\underline{\tilde{v}}}_{α β} = {𝕃}_{1} ( θ ) \frac{d }{d t} ( {\underline{I}}_{α β} + {\underline{\tilde{ι}}}_{α β} ) + ( ℝ + ω {𝕃}_{2} ) ( {\underline{I}}_{α β} + {\underline{\tilde{ι}}}_{α β} ) + ω ℙ ( θ ) [ \begin{matrix}0 \\ {Ψ}_{f}\end{matrix} ] \qquad ( 20 )$$

In addition, averaging equation 13 over one PWM period (and using equation 18) gives:

$${\underline{V}}_{α β} = {𝕃}_{1} ( θ ) \frac{{\underline{I}}_{α β} ( t + {T}_{pwm} ) - {\underline{I}}_{α β} ( t )}{{T}_{pwm}} + ( ℝ + ω {𝕃}_{2} ) {\underline{I}}_{α β} + ωℙ ( θ ) [ \begin{matrix}0 \\ Ψ\end{matrix} ] \qquad ( 21 )$$

But as long as T_{pwm} is sufficiently small, the above equation can be approximated as:

$${\underline{V}}_{α β} = {𝕃}_{1} ( θ ) \frac{d }{d t} ( {\underline{I}}_{α β} ) + ( ℝ + ω {𝕃}_{2} ) {\underline{I}}_{αβ} + ω ℙ ( θ ) [ \begin{matrix}0 \\ {Ψ}_{f}\end{matrix} ] \qquad ( 22 )$$

Then, subtracting this (equation 22) from equation 20, results in an equation for the oscillating part:

$${\underline{\tilde{v}}}_{α β} = {𝕃}_{1} ( θ ) \frac{d }{d t} ( {\underline{\tilde{ι}}}_{α β} ) + ( ℝ + ω {𝕃}_{2} ) {\underline{\tilde{ι}}}_{α β} \qquad ( 23 )$$

This equation is useful in determining shaft position from the current ripple—equation 23 does not contain a magnet term, and there is only one term that is a function of θ.

Shaft Position Calculation

In the previous section, equation 23 was determined for the ripple currents in the motor. In the present section, this result is built upon to develop the mathematics and the methods that can be used for shaft position calculation in the exemplary embodiment. Recall that a resolver gives sine and cosine signals such that, once decoded, determination of shaft position is a rather trivial matter. One can use a tracking loop architecture, a straight up arctangent approach, etc. Only one term in equation 23 is a function of θ, that is [symbol] ₁(θ), and it is made up of the functions sin and cos (exactly what is needed to determine shaft position).

Recovering SIN and COS

Using the ripple current equation (same as equation 23):

$${\tilde{\underline{v}}}_{α β} = {𝕃}_{1} ( θ ) \frac{d }{d t} ( {\tilde{\underline{ι}}}_{α β} ) + ( ℝ + ω {𝕃}_{2} ) {\tilde{\underline{ι}}}_{αβ} \qquad ( 24 )$$

And:

$$\begin{matrix}{𝕃}_{1} ( θ ) = \frac{{L}_{d} + {L}_{q}}{2} [ \begin{matrix}1 & 0 \\ 0 & 1\end{matrix} ] - \frac{{L}_{d} - {L}_{q}}{2} [ \begin{matrix}- cos 2 θ & sin 2 θ \\ sin 2 θ & cos 2 θ\end{matrix} ] & ( 25 ) \\ {𝕃}_{2} = ( {L}_{d} + {L}_{q} ) [ \begin{matrix}0 & - 1 \\ 1 & 0\end{matrix} ] & ( 26 ) \\ ℝ = [ \begin{matrix}R & 0 \\ 0 & R\end{matrix} ] & ( 27 )\end{matrix}$$

For most PWM systems, the magnitude of \tilde{ν}_{αβ} will be the bus voltage (unless one is using a multilevel inverter), and the magnitude of the current ripple \tilde{ι}_{αβ} is rarely greater than a couple of amps. For high voltage systems, the resistance is usually a couple of ohms and for low voltage systems the motor resistance is in the milliohms. The means that at low speeds, \tilde{ν}_{αβ}>>( [symbol] +ω [symbol] ₂)\tilde{ι}_{αβ}. So, the following approximation holds:

$${\underline{\tilde{v}}}_{α β} \approx {𝕃}_{1} ( θ ) \frac{d}{d t} ( {\tilde{\underline{ι}}}_{α β} ) \qquad ( 28 )$$

Then, integrating both sides, results in:

\tilde{λ}_{αβ}= [symbol] ₁(θ)\tilde{ι}_{αβ} (29)

Where

\tilde{λ}_{αβ}=∫\tilde{ν}_{αβ}dt (30)

\tilde{λ}_{αβ} can be determined directly from the PWM command. Then, over one PWM cycle, N samples of \tilde{λ}_{αβ} and \tilde{ι}_{αβ} can be accumulated to form the following 2×N matrices:

\tilde{Λ}_{αβ}=[\tilde{λ}_{αβ}(t₁)\tilde{λ}_{αβ}(t₂) . . . \tilde{λ}_{αβ}(t_{N-1})\tilde{λ}_{αβ}(t_{N})] (31)

And

Ĩ_{αβ}=[\tilde{ι}_{αβ}(t₁)\tilde{ι}_{αβ}(t₂) . . . \tilde{ι}_{αβ}(t_{N-1})\tilde{ι}_{αβ}(t_{N})] (32)

And because of equation 29, the following is also true:

\tilde{Λ}_{αβ}= [symbol] ₁(θ)Ĩ_{αβ} (33)

As long as N>2, it will be possible to solve for [symbol] ₁ (θ). To do this, both sides of equation 33 are first multiplied by Ĩ_{αβ}^{T} (the transpose of Ĩ_{αβ}) on the right. Which results in:

\tilde{Λ}_{αβ}Ĩ_{αβ}^{T}= [symbol] ₁(θ)Ĩ_{αβ}Ĩ_{αβ}^{T} (34)

But Ĩ_{αβ}Ĩ_{αβ}^{T} is just a 2×2 matrix which is guaranteed to be invertible, so [symbol] ₁(θ) can be solved for:

[symbol]

₁(θ)=\tilde{Λ}_{αβ}Ĩ_{αβ}^{T}(Ĩ_{αβ}Ĩ_{αβ}^{T})⁻¹ (35)

Now, this will be unpacked to further review the calculation.

$$\begin{matrix}{\tilde{Λ}}_{α β} {\tilde{I}}_{αβ}^{T} = {\sum }_{n = 1}^{N} {\tilde{\underline{λ}}}_{α β} ( {t}_{n} ) {\tilde{\underline{ι}}}_{α β}^{T} ( {t}_{n} ) & ( 36 ) \\ = {\sum }_{n = 1}^{N} [ \begin{matrix}{\tilde{λ}}_{α} ( {t}_{n} ) {\tilde{ι}}_{α} ( {t}_{n} ) & {\tilde{λ}}_{α} ( {t}_{n} ) {\tilde{ι}}_{β} ( {t}_{n} ) \\ {\tilde{λ}}_{β} ( {t}_{n} ) {\tilde{ι}}_{α} ( {t}_{n} ) & {\tilde{λ}}_{β} ( {t}_{n} ) {\tilde{ι}}_{β} ( {t}_{n} )\end{matrix} ] & ( 37 ) \\ = [ \begin{matrix}{\sum }_{n = 1}^{N} {\tilde{λ}}_{α} ( {t}_{n} ) {\tilde{ι}}_{α} ( {t}_{n} ) & {\sum }_{n = 1}^{N} {\tilde{λ}}_{α} ( {t}_{n} ) {\tilde{ι}}_{β} ( {t}_{n} ) \\ {\sum }_{n = 1}^{N} {\tilde{λ}}_{β} ( {t}_{n} ) {\tilde{ι}}_{α} ( {t}_{n} ) & {\sum }_{n = 1}^{N} {\tilde{λ}}_{β} ( {t}_{n} ) {\tilde{ι}}_{β} ( {t}_{n} )\end{matrix} ] & ( 38 )\end{matrix}$$

Similarly:

$$\begin{matrix}{\tilde{I}}_{α β} {\tilde{I}}_{αβ}^{T} = {\sum }_{n = 1}^{N} {\tilde{\underline{ι}}}_{α β} ( {t}_{n} ) {\tilde{\underline{ι}}}_{α β}^{T} ( {t}_{n} ) & ( 39 ) \\ = {\sum }_{n = 1}^{N} [ \begin{matrix}{\tilde{ι}}_{α} ( {t}_{n} ) {\tilde{ι}}_{α} ( {t}_{n} ) & {\tilde{ι}}_{α} ( {t}_{n} ) {\tilde{ι}}_{β} ( {t}_{n} ) \\ {\tilde{ι}}_{β} ( {t}_{n} ) {\tilde{ι}}_{α} ( {t}_{n} ) & {\tilde{ι}}_{β} ( {t}_{n} ) {\tilde{ι}}_{β} ( {t}_{n} )\end{matrix} ] & ( 40 ) \\ = [ \begin{matrix}{\sum }_{n = 1}^{N} {\tilde{ι}}_{α} ( {t}_{n} ) {\tilde{ι}}_{α} ( {t}_{n} ) & {\sum }_{n = 1}^{N} {\tilde{ι}}_{α} ( {t}_{n} ) {\tilde{ι}}_{β} ( {t}_{n} ) \\ {\sum }_{n = 1}^{N} {\tilde{ι}}_{β} ( {t}_{n} ) {\tilde{ι}}_{α} ( {t}_{n} ) & {\sum }_{n = 1}^{N} {\tilde{ι}}_{β} ( {t}_{n} ) {\tilde{ι}}_{β} ( {t}_{n} )\end{matrix} ] & ( 41 )\end{matrix}$$

Furthermore:

$${( {I}_{α β} {I}_{α β}^{T} )}^{- 1} = \frac{1}{\begin{matrix}( {\sum }_{n = 1}^{N} {\tilde{ι}}_{α} ( {t}_{n} ) {\tilde{ι}}_{α} ( {t}_{n} ) ) ( {\sum }_{n = 1}^{N} {\tilde{ι}}_{β} ( {t}_{n} ) {\tilde{ι}}_{β} ( {t}_{n} ) ) - \\ {( {\sum }_{n = 1}^{N} {\tilde{ι}}_{β} ( {t}_{n} ) {\tilde{ι}}_{α} ( {t}_{n} ) )}^{2}\end{matrix}} [ \begin{matrix}{\sum }_{n = 1}^{N} {\tilde{ι}}_{β} ( {t}_{n} ) {\tilde{ι}}_{β} ( {t}_{n} ) & - {\sum }_{n = 1}^{N} {\tilde{ι}}_{α} ( {t}_{n} ) {\tilde{ι}}_{β} ( {t}_{n} ) \\ - {\sum }_{n = 1}^{N} {\tilde{ι}}_{β} ( {t}_{n} ) {\tilde{ι}}_{α} ( {t}_{n} ) & {\sum }_{n = 1}^{N} {\tilde{ι}}_{α} ( {t}_{n} ) {\tilde{ι}}_{α} ( {t}_{n} )\end{matrix} ] \qquad ( 42 )$$

Now it will be apparent how to calculate the inductance matrix in equation 35. But recall its structure from equation 24. Letting

$$\overline{L} = \frac{{L}_{d} + {L}_{q}}{2} and Δ L = \frac{{L}_{d} - {L}_{q}}{2}$$

provides:

$$\begin{matrix}{𝕃}_{1} ( θ ) = [ \begin{matrix}\overline{L} + Δ L cos 2 θ & - Δ L sin 2 θ \\ - Δ L sin 2 θ & \overline{L} - Δ L cos 2 θ\end{matrix} ] & ( 43 ) \\ {𝕃}_{1} ( θ ) = [ \begin{matrix}{}_{1}^{1}{L}{}_{1}^{} ( θ ) & {}_{2}^{1}{L}{}_{1}^{} ( θ ) \\ {}_{1}^{2}{L}{}_{1}^{} ( θ ) & {}_{2}^{2}{L}{}_{1}^{} ( θ )\end{matrix} ] & ( 44 )\end{matrix}$$

So, to recover the sine's and cosine's from the inductance matrix:

$$\begin{matrix} COS = {}_{1}^{1}{L}{}_{1}^{} ( θ ) - {}_{2}^{1}{L}{}_{1}^{} ( θ ) & ( 45 ) \\ = {}_{1}^{1}{L}{}_{1}^{} ( θ ) - {}_{2}^{2}{L}{}_{1}^{} ( θ ) = ( \overline{L} + Δ L cos 2 θ ) - ( \overline{L} - Δ L cos 2 θ ) = 2 Δ L cos 2 θ & ( 46 ) \\ SIN = {}_{1}^{2}{L}{}_{1}^{} ( θ ) + {}_{2}^{1}{L}{}_{1}^{} ( θ ) & ( 47 ) \\ = {}_{1}^{2}{L}{}_{1}^{} ( θ ) + {}_{2}^{1}{L}{}_{1}^{} ( θ ) = ( - Δ L sin 2 θ ) + ( - Δ L sin 2 θ ) = - 2 Δ L sin 2 θ & ( 48 )\end{matrix}$$

Although the present disclosure has been described with respect to one or more particular embodiments, it will be understood that other embodiments of the present disclosure may be made without departing from the spirit and scope of the present disclosure. Hence, the present disclosure is deemed limited only by the appended claims and the reasonable interpretation thereof.

What is claimed is:

1. A method for determining a rotational position of a rotor of a brushless DC motor having at least a first phase and a second phase, the first phase and second phase being driven by a first pulse-width modulated (“PWM”) drive signal and a second PWM drive signal, the rotational position of the rotor being determined relative to a stator of the motor, the method comprising the steps of:
shifting a phase of the first PWM drive signal relative to a phase of the second PWM drive signal to produce a current ripple;
obtaining a plurality of measurements, over a sampling period, of a current of the first phase of the motor and a current of the second phase of the motor;
determining a current ripple based on the plurality of measurements;
determining an inductance of the stator over time based on the current ripple and the first and second PWM drive signals; and
determining the rotational position of the rotor based on the determined inductance.

2. The method of claim 1, wherein the brushless DC motor includes a third phase driven by a third PWM drive signal, the method further comprising the steps of:
shifting a phase of the third PWM drive signal relative to a phase of the first and second PWM drive signals; and
obtaining a plurality of measurements, over the sampling period, of a current of the third phase; and
wherein the step of determining an inductance of the stator over time is further based on the third PWM drive signal.

3. The method of claim 2, wherein the phase of each of the first, second, and third PWM drive signals is shifted 120° from each other.

4. The method of claim 1, wherein the number of measurements of the plurality of measurements during the sampling period (the “sampling rate”) is higher than a frequency of the PWM drive signals.

5. The method of claim 4, wherein the sampling rate is greater than 10 times more than the frequency of the PWM drive signals.

6. A controller for a three-phase BLDC motor having a saliency, the controller comprising:
a first PWM generator adapted to be in electrical communication with a first phase of the motor and configured to generate a first PWM drive signal, the first PWM drive signal having a drive frequency and a first signal phase;
a second PWM generator adapted to be in electrical communication with a second phase of the motor and configured to generate a second PWM drive signal, the second PWM drive signal having the drive frequency and a second signal phase which is different than the first signal phase;
a third PWM generator adapted to be in electrical communication with a third phase of the motor and configured to generate a third PWM drive signal, the third PWM drive signal having the drive frequency and a third signal phase which is different than the first and second signal phases; and
a ripple analyzer configured to sample a voltage of each of the PWM drive signals and a current of each phase of the motor at a sampling rate to determine a position of a rotor of the motor.

7. The controller of claim 6, wherein the ripple analyzer further comprises:
a current sensor configured to sample a current of each phase of the motor at a sampling rate and determine a ripple current;
a ripple flux generator configured to sample a voltage of each of the PWM drive signals at the sampling rate and determine a ripple flux; and
a position sensor in electrical communication with the current sensor and the ripple flux generator and configured to determine a position of a rotor of the motor based on the ripple current and the ripple flux.

8. A processor-based controller for a BLDC motor having a saliency, the controller comprising:
a processor;
interface circuitry configured to operably couple the processor to the motor; and
wherein the processor is programmed to:
provide a first PWM drive signal having a first voltage waveform to a first phase of the motor and a second PWM drive signal having a second voltage waveform to a second phase of the motor, the first and second PWM drive signals being phase-shifted relative to each other;
obtaining a plurality of measurements of a current of each phase of the motor over time; and
determine a position of a rotor of the motor based on the first and second voltage waveforms and the measured currents of the motor.

9. A method for fault detection of a brushless DC motor having at least a first phase and a second phase, the first phase and second phase being driven by a first pulse-width modulated (“PWM”) drive signal and a second PWM drive signal, the method comprising the steps of:
shifting a phase of the first PWM drive signal relative to a phase of the second PWM drive signal;
obtaining a plurality of measurements, over a sampling period, of a current of the first phase of the motor and a current of the second phase of the motor;
determining whether or not a current ripple exists based on the plurality of measurements; and
when the current ripple does not exist, providing a fault indication.

10. The method of claim 9, wherein determining whether or not a current ripple exists comprises the sub-steps of:
calculating, using the plurality of measurements; an average current over a PWM cycle;
calculating, using the plurality of measurements, a previous average current over a previous PWM cycle;
extrapolating a line through the calculated average current and the previous average current; and
subtracting the extrapolated line from the measured currents to determine if a current ripple remains.
